(19) United States
(12) Patent Application Publication
(10) Pub. No.: US 2015/0211146 A1
(43) Pub. Date: Jul. 30, 2015

(54) METHODS AND APPARATUSES FOR PREPARING A FERROELECTRIC CRYSTAL

(71) Applicant: Innovia Materials (Shanghai) Co., Ltd., Shanghai (CN)

(72) Inventors: Zibo Jiang, Shanghai (CN); Yongming Jiang, Zhejiang (CN)

(73) Assignee: Innovia Materials (Shanghai) Co., Ltd., Shanghai (CN)

(21) Appl. No.: 14/588,512

(22) Filed: Jan. 2, 2015

(30) Foreign Application Priority Data
Jan. 27, 2014 (CN) 201410039903.0

(51) Int. Cl. C30B 11/00; C30B 29/32; C30B 29/30

(52) U.S. Cl. CPC C30B 11/003; C30B 11/006; C30B 29/30; C30B 29/32

(57) ABSTRACT

Systems and methods are provided for preparing multi-component ferroelectric crystals (e.g., PMN-PT, amongst others) having piezoelectric properties. The crystals are fabricated using a system that employs multiple heaters and sensors that are located along the length of a crystal growth chamber. The heaters are controlled in concert, via a feedback system, to produce a temperature profile having a gradient that effectively moves along the length of the chamber, to suitably effectuate crystallization throughout the chamber, without need for the chamber to translate relative to the heater(s). During the crystallization process, the contents of the chamber may be mixed and/or homogenized via suitable agitation thereof, resulting in a multi-component ferroelectric crystal of desirable quality.

### FOREIGN PRIORITY

This application claims priority to Chinese Patent Application No. 201410039903.0, filed on Jan. 27, 2014, the content of which is incorporated by reference herein in its entirety.

### BACKGROUND

1. Field

Aspects described herein relate to methods and apparatuses for preparing a ferroelectric crystal.

2. Discussion of Related Art

The piezoelectric effect refers to the ability of certain materials to convert electrical energy to mechanical energy and/or vice versa. For example, a piezoelectric material may be able to generate an electric charge in response to an applied mechanical stress, or undergo mechanical actuation when an electric signal is applied thereto. Piezoelectric materials have been employed in a number of applications, such as in sensors, actuators, sound production and detection, high voltage generation, ultrasonics, sonar and scientific instruments that exhibit atomic precision (e.g., atomic force microscopes).

A number of materials, natural and man-made, exhibit piezoelectric behavior. A number of materials considered to be piezoelectric include Berlinite (AlPO₄), sucrose, quartz, Rochelle salt, topaz, tourmaline, apatite crystals, lead titanate, barium titanate, lead zirconate titanate, amongst others. As noted above, piezoelectric materials may be used in ultrasonic applications, that is, as a component in ultrasound transducers.

### SUMMARY

The present disclosure relates to preparing ferroelectric crystal(s) which, in some cases, may include multiple chemical components and/or exhibit piezoelectric behavior. The ferroelectric crystal(s) may be produced via coordinated programming of multiple heaters located along the length of a crystal growth chamber (e.g., crucible), so as to create a temperature profile having a particular gradient, or series of gradients, that effectively moves along the length of the chamber. This temperature profile causes desirable formation of contents (e.g., seed crystal, raw ceramic material(s), etc.) within the chamber into suitable ferroelectric crystal(s). Temperature sensors may also be provided along the chamber, for monitoring the temperature along the chamber and, hence, providing for an appropriate feedback mechanism for the system.

In various embodiments, an appropriate combination of seed crystal and raw ceramic composition may be placed within the crystal growth chamber. As the temperature along the chamber is monitored at various regions along the chamber, the heat output of the heater(s) may be adjusted accordingly to generate a desired temperature profile along the chamber. The raw ceramic composition may be melted, and as the temperature of the ceramic is cooled according to a suitable temperature profile, the seed crystal may provide the crystal structure for the ceramic composition to solidify or otherwise form to a desired multi-component ferroelectric crystal.

In various embodiments, the system may be configured so as to form such a temperature profile while substantially maintaining the position of the chamber relative to the heater(s) (e.g., with only a nominal amount of relative mechanical movement, if any, between the chamber or heaters along the length, or vertical direction, of the chamber) during the crystallization process. Though, during heating/crystallization, the contents of the chamber may be mixed and/or homogenized via an appropriate mechanism of agitation (e.g., rotator), so as to enhance formation of the multi-component ferroelectric crystal composition.

Such a system may be configured to suitably produce multi-component ferroelectric crystals, such as relaxor-type ferroelectric crystals (e.g., lead magnesium niobate lead titanate (PMN-PT)). The multi-component ferroelectric crystal(s) produced by this system may have desirable characteristics. For instance, the ferroelectric crystal(s) may have a diameter of greater than or equal to approximately 50 mm, and an effective length greater than or equal to approximately 150 mm, greater than or equal to approximately 200 mm, greater than or equal to approximately 250 mm, or another suitable length.

In an illustrative embodiment, a method for preparing a ferroelectric crystal is provided. The method includes placing a ceramic crystal composition within a crystal growth chamber having an upper end and a lower end; sensing temperature from a plurality of temperature sensors each located at a respective region of the chamber; adjusting heat output from a plurality of heaters based on the sensed temperatures, each of the heaters located at a position that corresponds to a respective temperature sensor; and agitating the chamber to mix the ceramic crystal composition within the chamber during heating of the ceramic crystal composition to form a multi-component ferroelectric crystal composition.

In another illustrative embodiment, a method for preparing a ferroelectric crystal is provided. The method includes placing a ceramic crystal composition within a crystal growth chamber; sensing temperature from at least one temperature sensor located adjacent to the chamber; and adjusting heat output from at least one heater based on the at least one sensed temperature to form a lead magnesium niobate-lead titanate multi-component ferroelectric crystal within the crystal growth chamber while substantially maintaining position of the chamber relative to the at least one heater.

In yet another illustrative embodiment, a system for preparing a ferroelectric crystal is provided. The system includes a ceramic crystal composition including a seed crystal and a sintered ceramic configured to be formed into a multi-component ferroelectric crystal composition; a crystal growth chamber having an upper end and a lower end; a plurality of temperature sensors located at respective regions along a surface of the chamber; a plurality of heaters configured to adjust heat output based on the sensed temperatures, each of the heaters located at a position that corresponds to a respective temperature sensor; a controller configured to adjust heat output from the plurality of heaters based on readings from the plurality of temperature sensors; and an agitator constructed and arranged to agitate the chamber for mixing the ceramic crystal composition within the chamber during heating of the ceramic crystal composition to form the multi-component ferroelectric crystal composition.

Various embodiments of the present disclosure provide certain advantages. Not all embodiments of the present disclosure share the same advantages and those that do may not share them under all circumstances. Various embodiments described may be used in combination and may provide additive benefits.

Further features and advantages of the present disclosure, as well as the structure of various embodiments of the present disclosure are described in detail below with reference to the accompanying drawings.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. Various embodiments of the present disclosure will now be described, by way of example, with reference to the accompanying drawings, in which:

FIG. 1 depicts a perspective view of a system for preparing ferroelectric materials in accordance with an embodiment;

FIG. 2 illustrates a cross-sectional view of a system for preparing ferroelectric materials in accordance with an embodiment;

FIG. 3 shows a perspective view of a portion of the system of FIGS. 1-2;

FIG. 4 shows a cross-sectional view of a system for preparing ferroelectric materials in accordance with an embodiment;

FIG. 5 depicts a cross-sectional view of the system of FIG. 4 in accordance with an embodiment;

FIG. 6 illustrates schematic temperature profiles with distance along a system at certain times, for preparing ferroelectric materials in accordance with an embodiment; and

FIG. 7 shows schematic temperature profiles with time at various regions of a system, for preparing ferroelectric materials in accordance with an embodiment.

### DETAILED DESCRIPTION

The inventors have appreciated that it would be beneficial to produce ferroelectric crystal(s) in a manner that is simple and effective. Embodiments described herein may be particularly useful in preparing multi-component ferroelectric crystals, such as relaxor-type ferroelectric crystals (e.g., PMN-PT), as understood by those skilled in the art. Multi-component ferroelectric crystals may be crystals that include multiple components (e.g., multiple chemical compounds). For example, a PMN-PT crystal is a binary component ferroelectric crystal that includes both lead magnesium niobate (e.g., Pb(Mg_{1/3}Nb_{2/3})O₃, amongst others) and lead titanate (e.g., PbTiO₃, amongst others). Other combinations are possible, for example, ternary component ferroelectric crystals (e.g., PMN-PIN-PT, Pb(Mg_{1/3}Nb_{2/3})O₃, Pb(In_{1/3}Nb_{2/3})O₃ and PbTiO₃, amongst others), quaternary component ferroelectric crystals, etc.

In some embodiments, the system includes a crystal growth chamber, such as a crucible. Multiple heaters and sensors may be located along the length of the crystal growth chamber. A controller may be configured to coordinate the heat output generated by each of the heaters, for example, through a feedback system based on temperatures monitored by respective sensors, so as to result in a temperature profile suitable for crystal growth in a desirable manner.

The heat generated from the heaters may be adjusted to form a desired temperature profile such that a temperature gradient, or series of gradients, effectively moves in suitable direction along the crystal growth chamber (e.g., along a longitudinal axis of the chamber), without need for the heater(s) and the chamber to move an appreciable distance relative to one another. That is, the system allows for temperature to be controlled precisely at various locations within the enclosed chamber.

Further, any requirement for the crystallization materials to be exposed to open air, which may result in defects or otherwise poorer crystal quality and/or loss of material (e.g., due to evaporation), may be removed. As a result, a single crystal (e.g., monocrystalline multi-component ferroelectric crystal), for example, having the same crystallographic orientation as the seed material, may be grown from the seed, and may be progressively formed along the length of its container.

For certain embodiments, some systems and methods described herein may be distinct from and an improvement over other mechanisms for producing ferroelectric crystals. For instance, another method of producing such crystals may also involve heating of polycrystalline material above its melting point and slowly cooling the material from the end at which a seed crystal is located. In doing so, a crystal growth chamber and a single heater may be mechanically configured to move relative to one another (e.g., in a vertical direction) such that the contents within the crucible are exposed to a particular temperature profile, via the single heater and movement of the crucible. As a result, the chamber moves physically with respect to the heater, or vice versa, to expose the heater at various times all along the surface of the chamber, resulting in a temperature distribution that is appropriate for crystal growth, typically for certain single component semiconductor crystals, such as gallium arsenide.

While the above method may be employed for certain embodiments, for other embodiments of the present disclosure, multiple heaters are already located along the length of the crystal growth chamber and configured such that the temperature distribution and gradient within the chamber will result in desirable crystal growth within the chamber. By incorporating the multiple heaters, suitably located along the chamber, there is no need for mechanical re-positioning of the chamber and the heaters with respect to one another to result in a preferred temperature distribution. One advantage of such a configuration is that crystal growth is able to be more accurately monitored and controlled than would otherwise be the case, where uncontrolled cooling effects from mechanical movement (e.g., vertical movement) may arise.

Further, during the crystal growth process, the crystal growth chamber may be subject to a suitable level of agitation, for stirring and/or homogenization of the molten material within the chamber. For example, the chamber may be rotated about a longitudinal axis L, clockwise and/or counter-clockwise, according to appropriate parameters. For some cases, well mixing of the molten material within the chamber during crystallization may result in an overall higher quality of ferroelectric crystal than would otherwise be the case without the agitation. It can be appreciated that any other suitable method of mixing the molten material within the chamber may be employed, for example, vibration, mechanical/shaft stirring, magnetic stirring, slight movement of the chamber vertically along the longitudinal axis L, though, with little to no need for net re-positioning of the chamber along the axis for temperature distribution purposes.

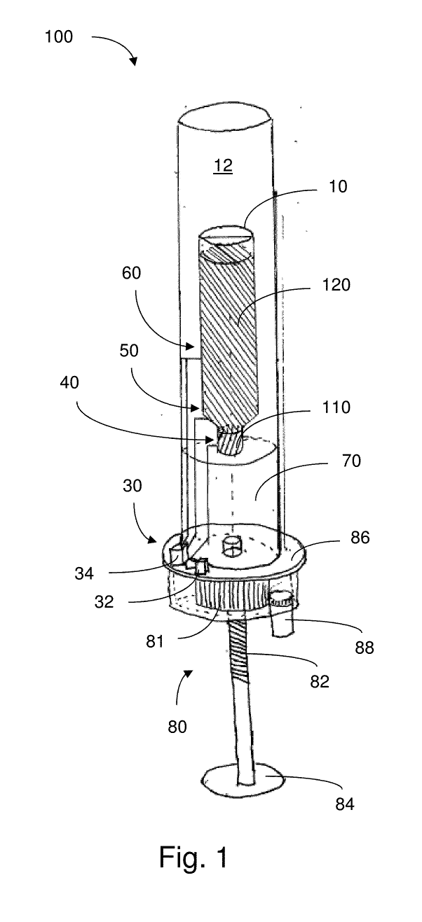

FIGS. 1-3 show an illustrative embodiment of a crystal growth system 100 used to prepare multi-component ferroelectric crystals. In this embodiment, the system 100 includes a crystal growth chamber 10 and an insulation region 12 surrounding the chamber 10.

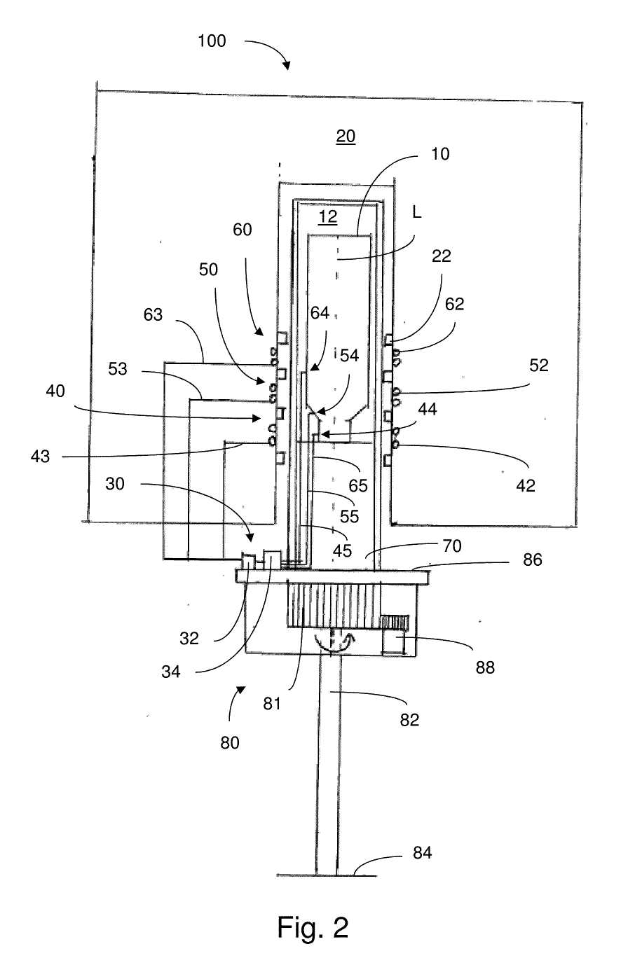

FIG. 1 shows the system 100 prior to incorporation of the chamber 10 within a furnace housing 20 for providing structural support as well as containing/controlling heat applied to the contents within the chamber. FIG. 2 shows the chamber 10 positioned within a suitable space or recess defined by the housing 20.

The chamber 10 may include any suitable composition that is able to provide an environment appropriate for crystallization of the contents held therein. That is, upon heating to relatively high temperatures, the chamber 10 should maintain its structure so as to support and contain the ceramic composition(s) and seed crystal located within the chamber.

In some embodiments, the chamber 10 is a crucible that is able to withstand high temperatures (e.g., in excess of 1500° C.. without degradation). Though, the chamber may include any suitable material, such as a metal (e.g., platinum, nickel, zirconium, etc.), quartz, ceramic (e.g., porcelain, alumina, zirconia, magnesia, etc.), or other composition(s) with similar characteristics. The chamber may have any appropriate dimensions, for example, a thickness of between 0.1 mm and 5 mm (e.g., between 0.2 mm and 2.0 mm), a width or diameter between outer surfaces of between 20 mm and 500 mm (e.g., between 50 mm and 100 mm), and/or may enclose a volume of between 100 cm³ and 10,000 cm³ (e.g., between 500 cm³ and 5,000 cm³).

As further shown, and noted above, the chamber 10 is surrounded by an insulation region 12, which may optionally include an insulative material that provides insulation as well as structural support for the chamber 10. The insulative material may also provide structural support for a thermally conductive rod 70 that extends along the longitudinal axis L from the chamber toward the agitator 80, and is attached or otherwise coupled thereto.

The insulative material may include any appropriate composition that exhibits thermally insulative properties, which may also be able to withstand relatively high temperatures, such as, for example, aluminum oxide, silicon oxide and/or other refractory materials (e.g., fire bricks, refractory board, refractory fibers, etc.) that are able to withstand temperatures exceeding 1500° C.

The insulation region 12 may also have dimensions that are suitable for crystal growth within the chamber 10. For example, in some embodiments, the diameter, or entirety of the insulating material thickness across, of the insulation region 12 from one side to another may be between 10 mm and 1000 mm (e.g., between 20 mm and 500 mm).

The system 100 includes a controller 30, for monitoring and regulating the temperature of the contents within the chamber 10. The controller 30 may incorporate any appropriate configuration and/or mechanism of operation. For example, the controller 30 may employ a proportional-integral-derivative (PID) control loop feedback mechanism, which calculates an error value difference between a measured value and the desired set point value. The overall error for such feedback mechanisms can be quite small, for example, having a precision that is within 0.5-1.0° C. Or, any other suitable feedback configuration may be employed, with suitable error levels. In this embodiment, the controller 30 includes a temperature manipulation unit 32 and a temperature monitoring unit 34. In some cases, the temperature monitoring unit 34 includes a computer for data acquisition and an optional display for providing temperature information, for example, to an operator or other observer. One or more of the units may be configured to send and receive signals from other parts of the controller, to control the overall temperature profile(s) of various regions of the chamber 10.

Each of these units for temperature control is connected or otherwise in communication with respective heaters and sensors of the system. For example, the system 100 includes heating regions 40, 50, 60, each having heaters 42, 52, 62 and sensors 44, 54, 64 associated therewith, located at appropriate locations along the length of the chamber 10. In some embodiments, and as shown in the figures, the heaters are located on the inner walls of housing 20 of the furnace and/or the surface of the chamber 10. A corresponding sensor may be located in close proximity to each heater (e.g., attached or coupled to the crystal growth chamber), so as to be able to monitor ambient temperatures. Accordingly, a number of appropriate temperature control loops may be formed between the respective heater(s), sensor(s) and controller, to control the heat output and, hence, temperature distribution along the chamber. In some embodiments, sensors may be attached to the chamber (or crucible), which may result in accurate temperature measurement and control. As depicted in the figures, the sensors 44, 54, 64 are located at appropriate locations on the crystal growth chamber.

The first heating region 40, including the first heater 42 and a corresponding first sensor (e.g., attached to the chamber), is located closer to the lower end of the chamber 10, and is connected to the controller 30 via respective signal lines 43, 45. As shown, for this embodiment, the first heater 42 is connected to the temperature manipulation unit 32 via the signal line 43, and the first sensor 44 is connected to the temperature monitoring unit 34 via the signal line 45.

The second heating region 50, which includes second heater 52 and a second sensor 54, is located above first heating region 40, and below the third heating region 60, and is connected to the controller 30 through respective signal lines 53, 55. In this embodiment, the second heater 52 is connected to the temperature manipulation unit 32 via the signal line 53, and the second sensor 54 is connected to the temperature monitoring unit 34 via the signal line 55.

The third heating region 60, including the third heater 62 and a third sensor, is located closer to the upper end of the chamber 10, and is connected to the controller 30 via signal lines 63, 65. Here, the third heater 62 is connected to the temperature manipulation unit 32 via the signal line 63, and the third sensor 64 is connected to the temperature monitoring unit 34 via the signal line 65.

Accordingly, the temperature manipulation unit 32 is connected to the heaters 42, 52, 62 via corresponding signal lines 43, 53, 63; and the temperature monitoring unit 34 is connected to the sensors 44, 54, 64, via corresponding signal lines 45, 55, 65.

Any suitable heater may be used. For example, the heater(s) may be infrared heaters, laser heaters, convective heaters, electrical heaters, semiconductor heaters (e.g., silicon carbide, molybdenum silicide, etc.) or any other suitable type of heater, as understood by those skilled in the art.

Any suitable temperature sensor may be employed. For instance, the sensor(s) may be thermocouples, resistance temperature detectors, silicon band gap temperature sensors, or any other appropriate type of sensor, as known to those skilled in the art. In some embodiments, the sensor(s) may include S-type, R-type and/or B-type thermocouples, as known to those skilled in the art, and which may employ platinum and/or a platinum/rhodium alloy. Such thermocouples are generally known to be stable at high temperatures (e.g., temperatures exceeding 1500° C.).

The heating regions, and/or heater(s) and sensor(s) associated therewith, may be located any suitable distance from one another along the chamber 10. In the illustrated embodiment, the distance between the first heating region 40 and the upper end of the chamber (e.g., upper region that is a relatively high temperature zone, kept above the melting point of the raw ceramic composition for the longest period of time during the crystallization process) is greater than the distance between the second heating region 50 and the upper end of the chamber. Also, as shown, the distance between the second heating region 50 and the upper end of the chamber is greater than the distance between the third heating region 60 and the upper end of the chamber.

Accordingly, for some embodiments, the first heating region 40 is generally kept as a relatively low temperature zone, where the temperature is lowered to below the melting point before the other heating regions, so that crystallization initially occurs here from the molten state; and the third heating region 60 is provided as a relatively high temperature zone, where the temperature is kept above the melting point of the raw ceramic composition for the longest period of time. That is, crystallization initially occurs at the first heating region 40, followed by the second heating region 50 and then finally the third heating region 60.

It can be appreciated that the temperature profile along the chamber may effectively move from the region where seed crystal is initially introduced into the chamber through the rest of the chamber, resulting in crystallization of the ceramic composition throughout the chamber (e.g., from the bottom to the top). As discussed further below, in this embodiment, the temperature at the bottom of the chamber is initially above the melting temperature of the raw ceramic composition and then cools down below the melting temperature, so as to induce crystal growth. With time, the temperature of the second region just above the initial location of the seed crystal also decreases, resulting in further crystal growth. Though, the temperature above the second region may remain above the melting point of the ceramic. As crystallization progresses up the chamber, the temperature continues to decrease with distance along the chamber, eventually resulting in crystallization of the entirety, or substantial portion, of the contents within the chamber.

In some embodiments, the distance between heating regions, and/or heater(s) and sensor(s), from one another may be at least 1 mm, at least 5 mm, at least 10 mm, at least 20 mm, at least 50 mm, or greater; or less than 50 mm, less than 20 mm, less than 10 mm, less than 5 mm, or any suitable combination of the above noted ranges. When several heating regions are provided, the distance between heating regions may be reduced, to allow for fine control of the temperature along the chamber. Though, conversely, when a small number of heating region are employed, the distance between heating regions may be comparatively larger. In various embodiments, and as shown, the system 100 may optionally include a thermally conductive rod 70 positioned underneath the chamber 10, for conducting heat away from the chamber during the process of crystallization. In some embodiments, as discussed above, the thermally conductive rod 70 may be coupled to and/or supported by the insulating material of the insulation region 12. The thermally conductive rod 70 may include any suitable material that is thermally conductive, for example, aluminum oxide, aluminum nitride, beryllium oxide, zinc oxide, bismuth, titanium, indium phosphide, zirconium oxide, perlite, polyethylene, polyurethane, amongst others, or combinations thereof.

The system 100 further includes an agitator 80, which provides for suitable mixing and/or homogenization of the initial molten ceramic composition(s) during crystallization within the chamber. The agitator 80 may also include a lifting mechanism that lifts the chamber 10 to an appropriate position for crystallization of the contents therein. In some cases, the agitator 80 provides the chamber 10 with additional structural support.

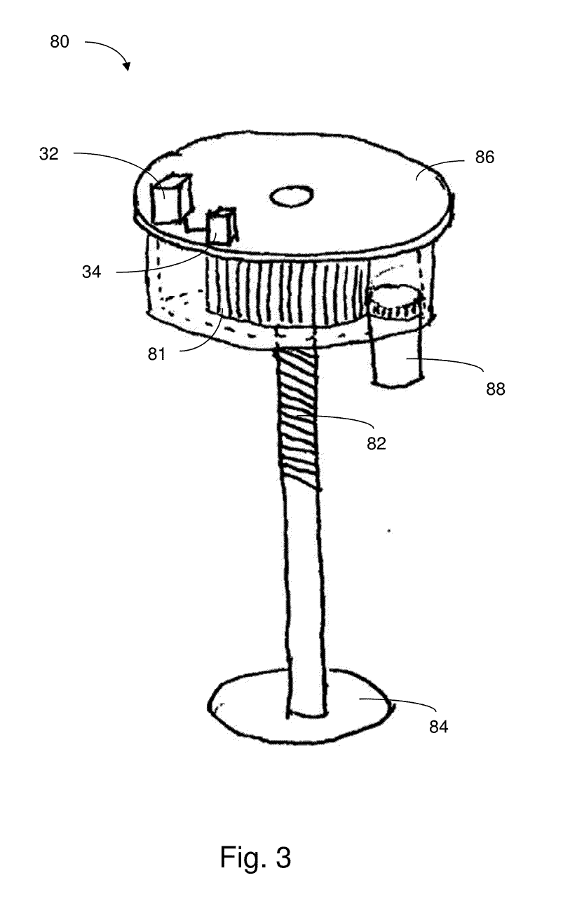

FIG. 3 depicts a close up view of the agitator 80, which includes a rotating unit 81 and a lifting unit 82, coupled with the chamber 10, for agitating and/or positioning the chamber within the housing 20. The rotating unit 81 and/or the lifting unit 82 may be coupled to a suitable driving mechanism (e.g., servo-motor, actuator, etc.), for actuation thereof, supported by a base 84. As shown, in this embodiment, the axis of rotation of the platform is coincident with the longitudinal axis L of the chamber 10.

In some embodiments, the rotating unit 81 may be used to assist stirring of the contents within the chamber 10 during the crystallization process. The rotating unit 81 may be actuated by any suitable mechanism, for example, via an electrical motor and belt configuration, or other arrangement.

In accordance with some embodiments, the rotating unit of the agitator may be configured to rotate the chamber by any suitable angular velocity, in a clockwise and/or counter-clockwise direction. For example, the rotating unit may rotate the chamber at an angular velocity of at least 20 rpm, at least 40 rpm, at least 60 rpm, at least 80 rpm, at least 100 rpm, at least 150 rpm, at least 200 rpm, less than 200 rpm, less than 150 rpm, less than 100 rpm, less than 80 rpm, less than 60 rpm, less than 40 rpm, less than 20 rpm, any suitable combination of these ranges; or outside of the above noted ranges.

In an example, during the crystallization process, a motor may drive the rotating unit to accelerate rotation of the chamber in a clockwise direction at about 10 rpm/min, up to an angular velocity of approximately 40 rpm. Then, the rotating unit may decelerate rotation of the chamber at about 10 rpm/min, followed by an acceleration of about 10 rpm/min in a counter-clockwise direction, up to an angular velocity of approximately 40 rpm/min. This cycle may be repeated any desirable amount of times. It can be appreciated that any mechanism and/or recipe of agitation may be employed for mixing the ceramic materials within the chamber during the crystallization process. As further discussed, such mixing during crystallization may result in higher quality crystal formation.

In some embodiments, the lifting unit 82 may be used to move the chamber 10 vertically along the longitudinal axis L when desired, for example, for suitably positioning the chamber 10 within the housing 20. That is, the lifting unit 82 may be used to provide entry of the chamber 10 into the housing 20, for the crystallization process to occur, and exit of the chamber 10 therefrom, once crystallization is complete. The lifting unit 82 may also move the chamber 10 relative to the housing, heater(s), sensor(s), etc. during the crystallization process, although, such movement is not a required aspect of the present disclosure.

The lifting unit 82 may be actuated by any appropriate mechanism. For example, the lifting unit 82 may be actuated through a servo motor and screw lift drive, or other configuration.

During use, the chamber 10, along with various components of the controller 30, are positioned upon a platform 86 and may be subject to any appropriate movement(s) thereof. For example, the rotating unit 81 may rotate the platform 86 in a clockwise and/or counter-clockwise direction, causing the chamber and other components located thereon to rotate therewith. Alternatively, the lifting unit 82 may cause the platform 86 to move vertically up and/or down which, in turn, moves the chamber and associated components as well.

Such an arrangement, where components coupled to the chamber (e.g., controller 30, temperature manipulation unit 32, temperature monitoring unit 34) move alongside the chamber itself, may be advantageous in that any wiring that forms an electrical signal connection with the controller 30 also moves with the chamber, reducing the possibility of tangling or other such interference with system operation.

As discussed herein, for various embodiments, the system may employ a suitable agitator so as to mix the contents within the chamber during the crystallization process. The inventor has recognized that without an appropriate agitating mechanism, it is otherwise difficult to maintain the homogeneity of the ceramic melt. That is, for multi-component crystal systems, compositional segregation may be more likely to occur than for a single component crystal system. Particularly for multi-component crystal systems, an agitator may be particularly useful during crystallization to maintain the melt composition to be relatively homogeneous.

Maintaining the melt composition to be relatively homogeneous may result in a single crystalline multi-component material that is substantially continuous, with a minimal or otherwise reduced amount of defects or grain boundaries. In some cases, the absence of defects associated with grain boundaries may impart monocrystalline materials uniquely enhanced properties, for example, mechanical, optical, electrical, amongst others.

Otherwise, when the melt composition is allowed to segregate to be more heterogeneous, the occurrence of nucleation at times that are undesirable for the overall quality of the resulting crystal product may be likely. Without an appropriate level of agitation of the raw ceramic composition, it is also more likely for twinning to occur, where multiple types of crystals are formed within a crystal ingot. When multiple types of crystals are formed within an ingot, additional processing may be necessary to separate the different crystal types from one another. Or, the radial temperature gradient may become undesirably high, resulting in thermal shock occurring during crystallization, where cracks and voids may arise within the final crystal product. Agitation may not only provide for suitable mixing of the contents within the chamber, but may also alleviate undesirable buildup of temperature throughout the chamber.

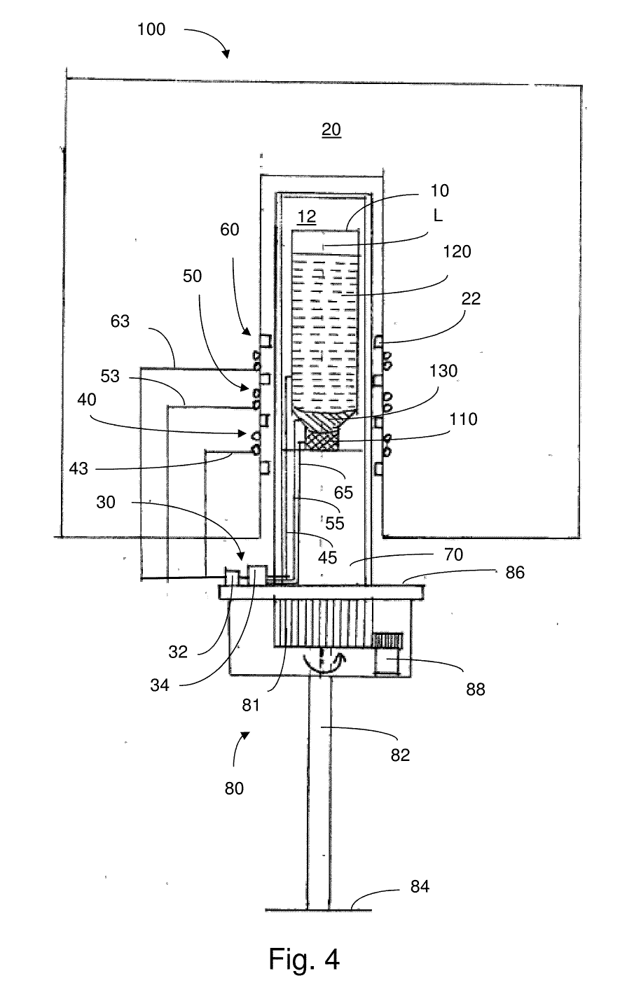

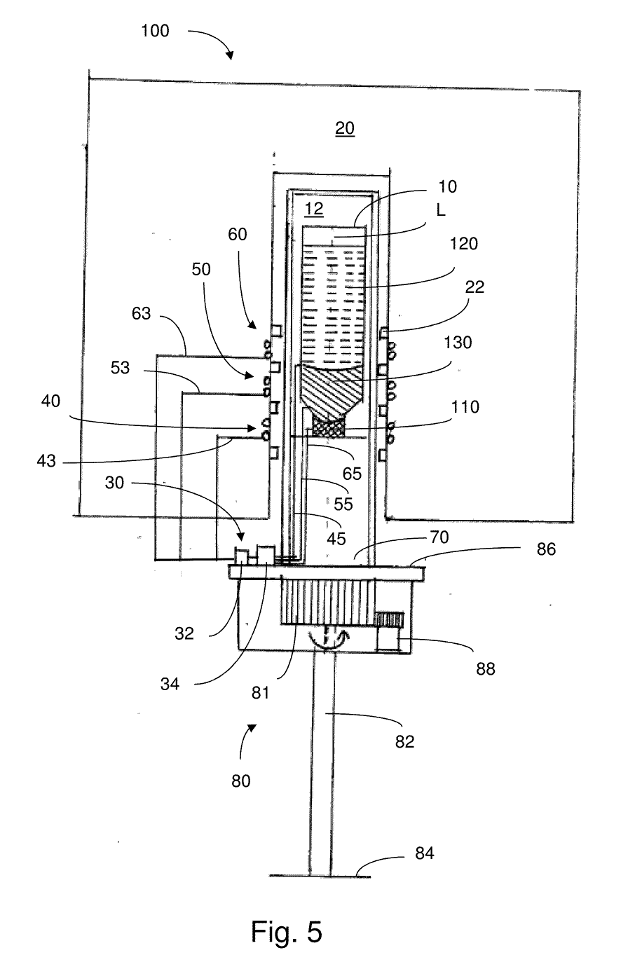

FIGS. 4-5 depict an illustrative embodiment of a system during crystallization. In various embodiments, a seed crystal and corresponding raw ceramic composition (e.g., PMN-PT, sintered or pre-sintered) are provided within the crucible as starting material for the final product. In some cases, the raw ceramic composition is provided as a refined powder mix compressed (e.g., using a cold isostatic press) into a green body and optionally sintered (e.g., at approximately 1000° C.. for 6 hours). The raw ceramic composition is then added to the seed crystal within the crystal growth chamber.

The raw ceramic composition may include any suitable material or combination of materials. For example, the raw ceramic composition may include one or more metal elements (e.g., added in the form of a metal oxide), such as lead, magnesium, niobium, titanium, zirconium, zinc, indium, bismuth, iron, scandium, ytterbium, antimony, cobalt, amongst others. Any suitable combination of metal elements may be used, as exemplified further below.

As generally understood by those skilled in the art, a seed crystal is a relatively small piece of single crystal, or polycrystalline, material from which a larger crystal of the same material may be grown. The larger crystal may be grown by exposing the seed crystal to a supersaturated solution, for example, a molten material resulting from heating of the raw ceramic composition, which is then cooled into the final crystalline form. The crystal grown on the seed crystal may generally resemble the texture of the seed crystal. For instance, a fabricated PMN-PT crystal having a [001] orientation would be grown from a seed crystal having a [001] orientation. That is, the seed crystal provides the template and lays the texture, or crystallographic orientation, for the crystal to be grown therefrom. A seed crystal may also act as a heterogeneous region, or nucleation point (having a low level of thermodynamic energy), where crystallization may be more prone to initiate.

Without wishing to be bound by theory, it is generally thought that crystal growth is derived from the physical intermolecular interaction that occurs between compounds in a supersaturated solution, where solute molecules are able to move about so as to freely interact with one another. The presence of the seed crystal expedites the crystallization process in that a pre-formed crystal structure is provided as the basis upon which the molecules may conform. That is, by having a crystal structure template, the intermolecular interactions that nucleate to form the larger crystal occur more readily than would otherwise be the case without the seed crystal, via random flow. For example, a seed crystal having a [001] orientation will likely induce crystal growth having a [001] orientation.

Accordingly, the seed crystal is placed at the bottom of the crucible and the raw ceramic composition (e.g., PMN-PT) is placed over the seed crystal. In some cases, the crucible is sealed, for example, by welding or placing a suitable covering thereon. The crystallization process is then initiated.

It can be appreciated that the composition of the seed crystal is not necessarily the same composition as that of the raw ceramic material, or the crystal product that is ultimately produced. For instance, in an example, a crystal seed of 70 mol. % PMN, 30 mol. % PT may be used to grow a crystal of 24 mol. % PIN 47 mol. % PMN 29 mol. % PT, where the overall crystal orientation remains the same as the seed orientation (e.g., [001] orientation seed used to grow [001] orientation crystal product).

In some embodiments, a seed crystal may have a composition that is different from the crystal ceramic that is grown therefrom, albeit where the orientation of the seed crystal and the grown crystal may be the same. For example, in some cases, TiO₂ having a [001] orientation may be used as a seed crystal to grow PMN-PT, also having a [001] orientation.

FIG. 4 depicts the system in operation near the beginning of the crystallization process. As noted above, a number of temperature control loops, or heating regions, may be formed at appropriate locations along the chamber 10. FIG. 4 shows three such heating regions 40, 50, 60, vertically distributed along the inner walls of housing 20, each heating region being independently controlled to achieve temperature profiles that are conducive to crystallization.

In this embodiment, the seed crystal 110 has been provided near the lower end of the chamber 10 and the initial raw ceramic composition 120 is provided over the seed crystal 110. The chamber is heated according to a suitable temperature distribution for a sufficient period of time (e.g., 10 hours or more) for the initial raw ceramic composition 120 to become molten. The heat output is then adjusted such that the temperature is lowered at the region where the seed crystal 110 is located (i.e., at the bottom of the chamber 10) to below the melting point of the ceramic, and crystallization is initiated within the initially raw ceramic composition. As noted above, for some embodiments, during crystallization, the agitator 80 drives rotational motion of chamber 10, for suitable mixing/homogenization thereof.

As provided in FIG. 4, the temperature closer to the upper end of the chamber 10 remains high, keeping the ceramic composition in a molten state. The temperature closer to the lower end of the chamber is comparatively lower, below the melting point of the ceramic, resulting in the formation of the grown ferroelectric crystal 130.

During the crystallization process, the lower temperature zone, which induces crystallization of the molten ceramic, effectively moves further along the longitudinal axis of the chamber 10 (e.g., shown in the figures to be in the upward direction), causing the grown ferroelectric crystal 130 to be formed in a continuous manner along the chamber. For example, FIG. 5 shows the system during crystallization at a later point in time than that shown in FIG. 4, where more grown ferroelectric crystal 130 is formed over the seed crystal 110 at the later stage.

For some embodiments, as shown in FIGS. 4-5, there may be a transition in width (e.g., diameter) from the smaller seed crystal 110 to the grown ferroelectric crystal 130. That is, the system or shape of the crystal growth chamber may be configured such that the width of the seed crystal 110 may be smaller than the width of the grown ferroelectric crystal 130. For example, the chamber may be tapered such that the region of the chamber where the seed crystal is located (e.g., seed region at the bottom of the chamber) may have a width smaller than that of the region of the chamber where the ferroelectric crystal is grown (e.g., growth region just above the seed region). In some embodiments, a transition angle (i.e., angle formed between the longitudinal axis L and the tapered wall of the chamber) of the chamber between the seed region and the growth region may be between 10 degrees and 90 degrees, between 30 degrees and 70 degrees, between 20 degrees and 80 degrees, between 30 degrees and 90 degrees, between 40 degrees and 60 degrees, or may fall outside of these ranges.

It can be appreciated that the system and associated chamber may be configured to have any suitable orientation. For example, the chamber may be arranged such that the longitudinal direction of the chamber lies horizontally, or along another direction, and that movement of the temperature gradient and, hence, crystallization occurs in a horizontal, or other, direction.

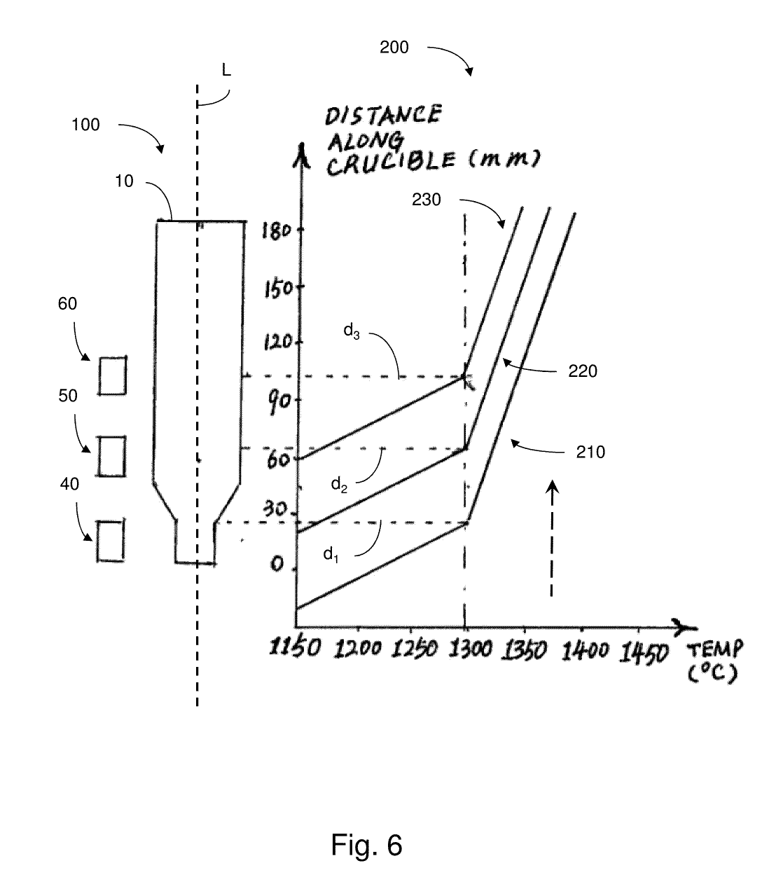

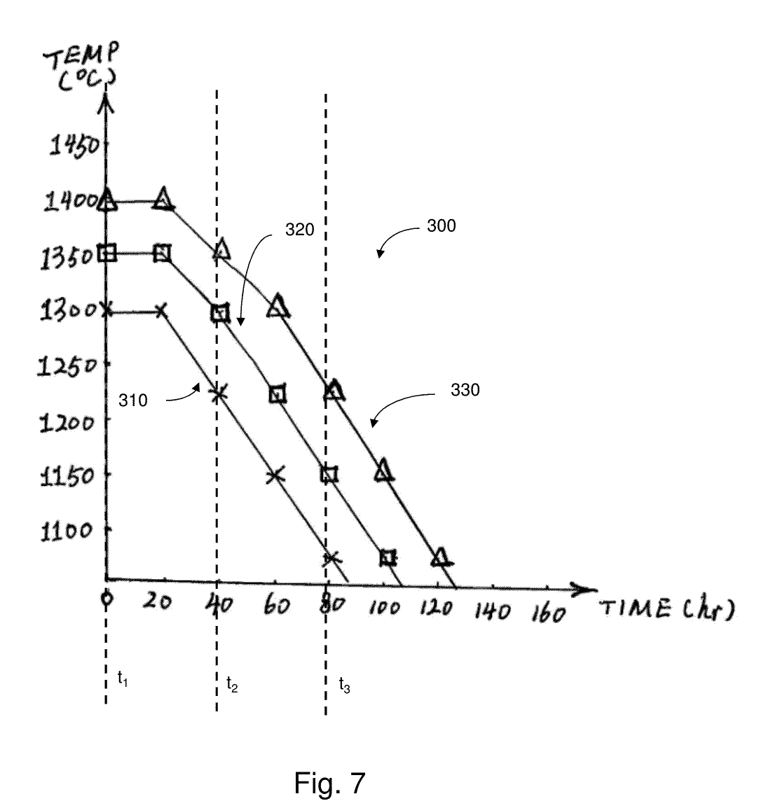

As noted above, the ability to control and coordinate multiple heaters and sensors located along the length of the crystal growth chamber may beneficially allow processes described herein to be customized and flexible. FIGS. 6-7 depict schematic illustrations of temperature profiles monitored at certain locations along the chamber, at particular times, as generated by the multiple heaters.

FIG. 6 shows the temperature profiles 200 along the length of the chamber 10, as generated by the heating regions 40, 50, 60 for successive points in time t₁, t₂, t₃ during crystallization. As shown, for this embodiment, the melting point of the raw ceramic composition within the chamber is approximately 1300° C. Though, it can be appreciated that any suitable temperature profile may be generated, for any suitable configuration of heating system and/or type of chamber for producing a desired crystal.

For this embodiment, the first curve 210 illustrates the temperature profile along the length of the chamber at a time t₁ (e.g., at approximately the beginning, less than 10 hours, less than 20 hours, less than 30 hours, less than 40 hours, etc., from the beginning of the process) that is relatively early during crystallization. The first curve 210 is characterized by a sharp increase in the temperature gradient over a distance (e.g., approximately 30 mm) between the bottom end of the chamber to a location d₁ along the chamber, up until the temperature where the melting point of the ceramic composition is reached. After reaching the melting point, the temperature gradient proceeds to level off further along the length of the chamber.

Various portions of the temperature profile may exhibit any suitable slope or gradient. For example, the temperature gradient of the initial part of the curve prior to reaching the melting point may be greater than 1° C./cm, greater than 5° C./cm, greater than 10° C./cm (e.g., between 10° C./cm and 50° C./cm, approximately 15-20° C./cm), greater than 20° C./cm, greater than 30° C./cm, greater than 40° C./cm, or greater than 50° C./cm; or less than 50° C./cm, less than 40° C./cm, less than 30° C./cm, less than 20° C./cm, less than 10° C./cm, or less than 5° C/cm; or any appropriate combination of the above ranges. In some cases, the temperature gradient of the initial part of the curve prior to reaching the melting point may fall outside of the above-noted ranges.

In this embodiment, location d₁ corresponds to the first heating region 40. As shown, upon reaching the melting point, the slope of the temperature gradient is reduced, yet the temperature remains above the melting point. Accordingly, at time t₁, a suitable seed crystal is provided at the lower end of the chamber from the bottom end of the chamber up to the location d₁. The remainder of the ceramic composition, shown in FIG. 6 as the portion that extends beyond location d₁ up to the upper end of the chamber, is in a molten state.

As further shown in FIG. 6, the second curve 220 depicts the temperature profile along the length of the chamber at a later point in time t₂ (e.g., after approximately 40 hours, after 10-80 hours, after 20-70 hours, after 30-50 hours, etc., from the beginning of the process) during the process. Here, the temperature profile initially generated has effectively moved further along the longitudinal axis L, as illustrated by the dashed arrow, such that the temperature reaches the melting point of the ceramic composition at another location d₂ along the chamber. As shown, location d₂ corresponds to the second heating region 50. That is, the shape of the second curve 220 is essentially the same as that of the first curve 210, though, the profile is displaced upward along the length of the chamber. At time t₂, crystal formation has occurred in the region from the lower end of the chamber to up to the location d₂ along the chamber. Accordingly, the remaining portion of the ceramic that extends beyond the location d₂ up to the upper end of the chamber, which is subject to a temperature above the melting point, is molten.

The third curve 230 shows the temperature profile along the length of the chamber at an even later time t₃ (e.g., after approximately 80 hours, after 50-120 hours, after 60-100 hours, after 70-90 hours, etc., from the beginning of the process) during crystallization. Similar to that discussed above, the shape of the third curve 230 is substantially similar to the shape of the first and second curves 210, 220, yet shifted further along the length of the chamber. At time t₃, the size of the crystal has grown up to the location d₃ along the chamber, with the portion of the ceramic extending beyond the location d₃ up to the upper end of the chamber remaining molten. Here, location d₃ corresponds to the third heating region 60.

As a result, the heating system is coordinated such that the temperature profile that is initially created effectively moves along the longitudinal axis of the chamber (e.g., in a vertically upward direction as depicted by the dashed arrow) as crystallization elapses. This is contrast with other methods where a single heater creates a temperature profile and physical movement of the chamber relative to the heater along the longitudinal axis must occur for the temperature profile to be applied to other regions of the chamber.

The temperature profile may effectively move along the length of the chamber at any suitable rate. In some embodiments, the system may be configured to control the heaters such that the temperature profile moves along the length of the chamber at a rate of less than 30 mm/hr, less than 20 mm/hr (e.g., between approximately 0.1-20.0 mm/hr), less than 15 mm/hr, less than 10 mm/hr (e.g., between approximately 0.2-10 mm/hr), less than 8 mm/hr, less than 6 mm/hr, less than 4 mm/hr, less than 2 mm/hr, less than 1 mm/hr, less than 0.8 mm/hr, less than 0.6 mm/hr, less than 0.4 mm/hr, or less than 0.2 mm/hr. The rate at which the temperature profile moves may depend on the particular crystal composition to be formed. The system may be configured to control the heaters such that the temperature profile moves at a rate outside of the above noted ranges.

FIG. 7 shows an embodiment of a number of temperature profiles 300 as a function of time, as generated by the heating regions 40, 50, 60 for particular locations d₁, d₂, d₃ during crystallization. In this embodiment, the curve 310 corresponds approximately to the temperature monitored over time at the location d₁, which is at the first heating region 40. The curve 320 approximately reflects the temperature as a function of time at the location d₂, which is at the second heating region 50. Similarly, the curve 330 corresponds approximately to the temperature monitored with time at the location d₃, which is at the third heating region 60.

In this embodiment, as shown, the beginning portion (e.g., less than 20 hours, less than 15 hours, less than 10 hours, etc.) of each of the curves 310, 320, 330, corresponding to heating regions 40, 50, 60, are held steady. This is to ensure that the ceramic composition melts thoroughly, for subsequent crystallization thereof. As further shown, the temperature at each of heating regions 40, 50, 60 is reduced, so as to effectively cause the temperature gradient along the length of the chamber to move further (e.g., upward) along the longitudinal axis of the chamber. The temperature profiles shown in this embodiment may be suitable for crystallization of PMN-PT, or another appropriate crystalline material.

As shown, the initial temperature at the first heating region 40 corresponding to curve 310 which, in some cases, may be considered as a seed zone, may be approximately 1300° C. or lower. Though, it can be appreciated that the first heating region 40, or another appropriate heating region at or in relatively close proximity to the seed crystal, may be set to any suitable temperature(s), depending on the desired type of crystal to be produced, or in accordance with other desired factor(s). In some embodiments, the initial temperature of a region at or near the seed crystal may be less than or equal to 1500° C. (e.g., between 1000° C. and 1500° C.), less than or equal to 1450° C., less than or equal to 1400° C., less than or equal to 1350° C., less than or equal to 1300° C. (e.g., between 1100° C. and 1300° C.), less than or equal to 1250° C., less than or equal to 1200° C., less than or equal to 1100° C., less than or equal to 1000° C., or any other suitable range of temperature(s).

After the initial temperature of each of the heating regions is held steady for a sufficient period of time, for some embodiments, the temperature is suitably reduced. In some cases, the rate of temperature reduction for each of the heating regions is substantially similar, for example, so that the overall shape of the temperature profile remains generally the same as it migrates along the crystal growth chamber.

The system may be configured to have any suitable rate of temperature reduction for one or more of the heating regions (e.g., any one or more of a first, second, third heating region 40, 50, 60, or another configuration). In some embodiments, the rate of temperature reduction for one or more of the heating regions is less than or equal to 30° C./hr, less than or equal to 20° C./hr, less than or equal to 10° C./hr, less than or equal to 5° C./hr (e.g., between 2° C./hr and 5° C./hr), less than or equal to 4° C/hr (e.g., between 1° C/hr and 4° C/hr), less than or equal to 3° C/hr, less than or equal to 2° C/hr, or less than or equal to 1° C/hr. It can be appreciated that the rate of temperature change (or reduction) for multiple heating regions may be approximately the same, or may be different from one another.

The initial temperature of the second heating region 50 corresponding to curve 320, which may be considered as a crystallization zone, may be approximately between 1290° C. and 1360° C. The heaters of the second heating region 50, or another appropriate heating region located at an intermediate position past the seed crystal (e.g., approximately 60 mm from the lower end of the chamber, approximately 30 mm from the initial location of the seed crystal) may be controlled to output heat that gives rise to any suitable temperature, depending on the type of crystallization, or other consideration(s). For instance, in some embodiments, the initial temperature of a region at the intermediate position past the seed crystal may be between 1000° C. and 1600° C., between 1100° C. and 1500° C., between 1200° C. and 1400° C., between 1300° C. and 1400° C., between 1290° C. and 1360° C., between 1290° C. and 1310° C., or between 1300° C. and 1350° C., or any other suitable range of temperature(s).

The initial temperature of the third heating region 60 corresponding to curve 330, which may be considered initially as a molten zone, may be approximately 1360° C. or greater. The third heating region 60, or another heating region located furthest from the seed zone (e.g., approximately 90-120 mm from the lower end of the chamber, approximately 60-90 mm from the initial location of the seed crystal) may be set to any appropriate temperature, for example, based on the type of crystal to be formed. In various embodiments, the initial temperature of a heating region of the chamber furthest from the seed crystal may be greater than 1000° C., greater than 1100° C., greater than 1200° C., greater than 1300° C., greater than 1350° C. (e.g., approximately 1360-1400° C.), greater than 1400° C., greater than 1450° C., greater than 1500° C., or any other suitable range of temperature(s). For various embodiments, it may be beneficial for the molten zone during crystallization to exhibit relatively high temperatures (e.g., approximately 1380° C. for PMN-PT crystallization), for example, so that raw material may be more thoroughly and actively mixed. Though, it can be appreciated that temperatures that are excessively high may result in degradation of the raw material(s) and/or parts of the system itself (e.g., chamber, heaters, sensors, etc.).

Once the crystallization process within the chamber is completed, or substantially complete, for some embodiments, the temperature may be gradually decreased to near ambient conditions. For example, the rate of temperature decrease may be less than 80° C/hr, less than 60° C/hr, less than 40° C/hr, less than 30° C/hr, less than 20° C/hr, less than 10° C/hr, or less than 5° C/hr. Once the chamber is sufficiently cool, the vertical lift may be used to carry the chamber out of the furnace housing, for disassembly thereof.

As discussed above, systems and methods according to the present disclosure may be employed for fabricating multi-component ferroelectric crystals, such as relaxor ferroelectric crystals.

In an example, the resultant PMN-PT crystal boule may be about 250 mm in length, yet approximately 150 mm, or another dimension, may be usable for a suitable application. In various embodiments, the usable part of a crystal boule, as prepared herein, may have a direct electromechanical coupling coefficient (k₃₃) measured to be greater than 0.75, greater than 0.80, greater than 0.85 (e.g., approximately 0.9), or greater than 0.90, where 1.0 is considered to be the maximum theoretical efficiency and 0.0 is considered to be completely inefficient. As determined herein, the direct electromechanical coupling coefficient (k₃₃) is measured by the IEEE Standard on Piezoelectricity 176-1987.

In some embodiments, the crystal boule (e.g., [001] orientation PMN-PT) may have a direct charge coefficient (d₃₃) measured to be greater than 650 pC/N (picoCoulombs/Newton), greater than 700 pC/N, greater than 750 pC/N, greater than 800 pC/N, greater than 900 pC/N, greater than 1000 pC/N, greater than 1200 pC/N, greater than 1300 pC/N, greater than 1400 pC/N, greater than 1600 pC/N, greater than 1800 pC/N, greater than 2000 pC/N (e.g., approximately 2000 pC/N) , greater than 2200 pC/N; or less than 2200 pC/N less than 2000 pC/N, less than 1800 pC/N, less than 1600 pC/N, less than 1400 pC/N, less than 1200 pC/N, less than 1000 pC/N, less than 900 pC/N, less than 800 pC/N, less than 700 pC/N, or combinations of any of the above noted ranges (e.g., between 1300 pC/N and 2200 pC/N). As determined herein, the direct charge coefficient (d₃₃) is measured by the IEEE Standard on Piezoelectricity 176-1987.

In some cases, relaxor ferroelectric crystals, may have a relatively high dielectric constant. For example, a dielectric constant K₃^{T} for a relaxor ferroelectric crystal (e.g., [001] orientation PMN-PT crystal) may be greater than 4000, greater than 5000, greater than 6000, greater than 7000, greater than 8000; or between 4000 and 9000, between 4500 and 8000, or between 5000 and 7000. As determined herein, the dielectric constant (K₃^{T}) is measured by the IEEE Standard on Piezoelectricity 176-1987.

Those of skill in the art will appreciate that a piezoelectric ceramic having a direct electromechanical coupling coefficient (k₃₃) of greater than 0.75 and/or a direct charge coefficient (d₃₃) of greater than 650 pC/N is considered to be acceptable. Those of skill in the art will also appreciate that a piezeoelectric ceramic having a dielectric constant K₃^{T} of 3800 may be considered to be acceptable. Accordingly, piezoelectric materials (e.g., PMN-PT) produced using systems and methods described herein may exhibit superior performance (e.g., sensitivity, bandwidth, etc.) in comparison to existing materials.

In various embodiments, relaxor ferroelectrics may have characteristics that allow for electromechanical coupling of the crystal with enhanced sensitivity and bandwidth as compared to other types of crystals, particularly when used in ultrasound applications. Although, it can be appreciated that relaxor ferroelectric crystals described herein may be used for any suitable application.

In some embodiments, the crystals produced herein are considered to be soft ceramics, as opposed to hard ceramics, as understood by those of skill in the art. That is, for example, small amounts of a donor dopant may be added to a ceramic formulation to create metal (e.g., cation) vacancies within the overall crystal structure. Such vacancies may enhance the effects of extrinsic factors on the piezoelectric properties of the ceramic. For instance, soft ceramics may exhibit comparatively larger displacements, higher sensitivity and wider signal band widths relative to hard ceramics.

The ferroelectric crystal produced using systems and methods described herein may include any suitable composition, for example, those that are multi-component in nature. In some embodiments, as discussed above, the ferroelectric crystal may include lead magnesium niobate lead titanate, or PMN-PT. In some cases, the PMN-PT may have a formula Pb(Mg_{1/3}Nb_{2/3})₁₋ₓTiₓO₃, or (1−y)Pb(Mg_{1/3}Nb_{2/3})₁₋ₓTiₓO₃+yPb(R, Nb)O₃, in which each of x and y may be a value between 0.0 and 0.70, between 0.0 and 0.50, or between 0.0 and 0.35, and R may be an element such as one of Al, Ba, Bi, Ca, Co, Cr, Fe, Li, Lu, Mn, Sc, Sn, Sr, Tm, In, Co, Zr, Zn, Yb amongst others. For example, for Pb(Mg_{1/3}Nb_{2/3})₁₋ₓTiₓO₃, x may be a value between 0.0 and 0.50; and for (1−y)Pb(Mg_{1/3}Nb_{2/3})₁₋ₓTiₓO₃+yPb(R, Nb)O₃, x may be a value between 0.0 and 0.35, y may be a value between 0.0 and 0.50, and R may be an element such as one of Al, Ba, Bi, Ca, Co, Cr, Fe, Li, Lu, Mn, Sc, Sn, Sr, Tm, In, Co, Zr, Zn, Yb.

Or, in various embodiments, the ferroelectric crystal may include PSNT (e.g., Pb[(Sc_{1/2}Nb_{1/2})Ti]O₃, or Pb(Sc_{1/2}Nb_{1/2})₁₋ₓTiₓO₃ where x is a value between 0.0 and 0.60, between 0.0 and 0.50, between 0.0 and 0.43 (e.g., approximately 0.425), near the morphotropic phase boundary of the material), lead zinc niobate lead titanate, or PZNT (e.g., Pb[(Zn_{1/3}Nb_{2/3})Ti]O₃), amongst others. For example, the PZNT may have a formula Pb(Zn_{1/3}Nb_{2/3})₁₋ₓTiₓO₃, in which x is a value between 0.01 and 0.30, or between 0.05 and 0.10.

As discussed above, multi-component ferroelectric crystals produced according to systems and methods described herein may include ferroelectric crystals that include two or more types of crystal components. For instance, a suitable ferroelectric crystal may include lead indium niobate-lead titanate and/or lead indium niobate-lead magnesium niobate-lead titanate, where a percentage of the lead indium niobate composition may be between 10 mol. % and 40 mol. %, between 20 mol. % and 30 mol. % (e.g., approximately 24 mol. %), a percentage of lead magnesium niobate composition may be between 20 mol. % and 70 mol. %, between 30 mol. % and 50 mol. % (e.g., approximately 47 mol. %, and a percentage of lead titanate composition may be between 10 mol. % and 50 mol. %, between 20 mol. % and 40 mol. % (e.g., approximately 29 mol. %).

Having thus described several aspects of at least one embodiment of the present disclosure, it is to be appreciated various alterations, modifications, and improvements will readily occur to those skilled in the art. For example, embodiments of the present disclosure may be used for a number of different applications, such as ultrasound, SONAR, amongst others. Such alterations, modification, and improvements are intended to be part of this disclosure, and are intended to be within the spirit and scope of the present disclosure. Accordingly, the foregoing description and drawings are by way of example only.

1. A method for preparing a ferroelectric crystal, comprising:
placing a ceramic crystal composition within a crystal growth chamber having an upper end and a lower end;
sensing temperature from a plurality of temperature sensors each located at a respective region of the chamber;
adjusting heat output from a plurality of heaters based on the sensed temperatures, each of the heaters located at a position that corresponds to a respective temperature sensor; and
agitating the chamber to mix the ceramic crystal composition within the chamber during heating of the ceramic crystal composition to form a multi-component ferroelectric crystal composition.

2. The method of claim 1, wherein the multi-component ferroelectric crystal composition is a relaxor ferroelectric crystal composition.

3. The method of claim 2, wherein the relaxor ferroelectric crystal composition has a direct electromechanical coupling coefficient k₃₃ of at least 0.80.

4. The method of claim 1, wherein sensing temperature from the plurality of temperature sensors includes sensing a first temperature from a first temperature sensor at a first region of the chamber and sensing a second temperature from a second temperature sensor at a second region of the chamber, wherein a distance between the first region and the upper end of the chamber is greater than a distance between the second region and the upper end of the chamber.

5. The method of claim 4, wherein adjusting heat output from the plurality of heaters includes adjusting heat output from a first heater located at the first region of the chamber based on the sensed first temperature and adjusting heat output from a second heater located at the second region of the chamber based on the sensed second temperature.

6. The method of claim 5, wherein adjusting heat output from the first heater includes modifying temperature at the first region of the chamber to a temperature of less than or equal to 1500° C.

7. The method of claim 6, wherein adjusting heat output from the first heater includes modifying temperature at the first region of the chamber to a temperature of between 900° C. and 1500° C.

8. The method of claim 5, wherein adjusting heat output from the second heater includes modifying temperature at the second region of the chamber to a temperature between 1000° C. about 1600° C.

9. The method of claim 1, wherein adjusting heat output from at least one of the plurality of heaters includes forming a temperature profile at a respective region of the chamber having a gradient of between 10° C./cm and 50° C./cm.

10. The method of claim 1, wherein adjusting heat output from at least one of the plurality of heaters includes forming and maintaining a temperature profile at a respective region of the chamber for at least 10 hours.

11. The method of claim 1, wherein adjusting heat output from at least one of the plurality of heaters includes forming and moving a temperature profile at a respective region of the chamber toward the upper end of the crystal growth chamber.

12. The method of claim 11, wherein adjusting heat output from at least one of the plurality of heaters includes moving the temperature profile at a rate of between 0.1 and 20.0 mm/hr.

13. The method of claim 1, wherein adjusting heat output from at least one of the plurality of heaters includes decreasing temperature at a respective region of the chamber by a rate of less than or equal to 10° C./hr.

14. The method of claim 5, wherein sensing temperature from the plurality of temperature sensors includes sensing a third temperature from a third temperature sensor located at a third region of the chamber, wherein the distance between the second region and the upper end of the chamber is greater than a distance between the third region and the upper end of the chamber, and wherein adjusting heat output from the plurality of heaters includes adjusting heat output from a third heater located at the third region of the chamber based on the sensed third temperature.

15. The method of claim 14, wherein adjusting heat output from the third heater includes modifying temperature at the third region of the chamber to a temperature of greater than 1000° C.

16. The method of claim 14, wherein adjusting heat output from the third heater includes decreasing the temperature at the third region of the chamber at a rate of less than or equal to 10° C./hr.

17. The method of claim 1, wherein agitating the chamber includes rotating the chamber at an angular velocity of less than 100 rpm.

18. The method of claim 17, wherein agitating the chamber includes rotating the chamber at an angular velocity of between 20 rpm and 60 rpm.

19. The method of claim 1, wherein the ceramic crystal composition includes at least one of a sintered ceramic and a seed crystal.

20. The method of claim 19, wherein the sintered ceramic includes at least one of lead, magnesium, niobium, titanium, zinc and indium.

21. The method of claim 1, wherein the multi-component ferroelectric crystal composition includes at least one of a binary component ferroelectric crystal composition, a ternary component ferroelectric crystal composition and a quaternary component ferroelectric crystal composition.

22. The method of claim 1, wherein the multi-component ferroelectric crystal composition includes at least one of lead magnesium niobate lead titanate, Pb(Mg_{1/3}Nb_{2/3})₁₋ₓTiₓO₃, and (1−y)Pb(Mg_{1/3}Nb_{2/3})₁₋ₓTiO+yPb(R, Nb)O₃, in which x is a value between 0.0 and 0.70, y is a value between 0.0 and 0.70, and R is one of Al, Ba, Bi, Ca, Co, Cr, Fe, Li, Lu, Mn, Sc, Sn, Sr, Tm, In, Co, Zr, Yb.

23. The method of claim 1, wherein the multi-component ferroelectric crystal composition includes at least one of lead zinc niobate lead titanate and Pb(Zn_{1/3}Nb_{2/3})₁₋ₓTiₓO₃, in which x is a value between 0.01 and 0.30.

24. The method of claim 1, wherein the multi-component ferroelectric crystal composition includes at least one of lead indium niobate lead titanate and lead indium niobate lead magnesium niobate lead titanate, wherein a percentage of lead indium niobate composition is between 10% and 40%, a percentage of lead magnesium niobate composition is between 20% and 70% and a percentage of lead titanate composition is between 10% and 50%.

25. A system for preparing a ferroelectric crystal, comprising:
a ceramic crystal composition including a seed crystal and a sintered ceramic configured to be formed into a multi-component ferroelectric crystal composition;
a crystal growth chamber having an upper end and a lower end;
a plurality of temperature sensors located at respective regions along a surface of the chamber;
a plurality of heaters configured to adjust heat output based on the sensed temperatures, each of the heaters located at a position that corresponds to a respective temperature sensor;
a controller configured to adjust heat output from the plurality of heaters based on readings from the plurality of temperature sensors; and
an agitator constructed and arranged to agitate the chamber for mixing the ceramic crystal composition within the chamber during heating of the ceramic crystal composition to form the multi-component ferroelectric crystal composition.

26. The system of claim 25, wherein the ceramic crystal composition includes at least one of a sintered ceramic and a seed crystal.

27. The system of claim 26, wherein the sintered ceramic includes at least one of lead, magnesium, niobium, titanium, zinc and indium.

28. The system of claim 25, wherein the plurality of temperature sensors includes a first temperature sensor located at a first region of the chamber and a second temperature sensor located at a second region of the chamber, and the plurality of heaters includes a first heater located at the first region of the chamber and a second heater located at the second region of the chamber, wherein a distance between the first region and the upper end of the chamber is greater than a distance between the second region and the upper end of the chamber.

29. The system of claim 28, wherein the plurality of temperature sensors includes a third temperature sensor located at a third region of the chamber, and the plurality of heaters includes a third heater located at the third region of the chamber, wherein a distance between the second region and the upper end of the chamber is greater than the distance between the third region and the upper end of the chamber.

30. The system of claim 25, wherein the crystal growth chamber includes a crucible including platinum.

31. The system of claim 25, further comprising an insulating layer positioned between the crystal growth chamber and at least one of the plurality of heaters.

32. The system of claim 31, further comprising a heat conducting rod coupled to the insulating layer.

33. The system of claim 25, wherein at least one of the plurality of temperature sensors is attached to the crystal growth chamber.
